(19) United States
(12) Patent Application Publication
(10) Pub. No.: US 2008/0024237 A1
(43) Pub. Date: Jan. 31, 2008

(54) Oscillator

(75) Inventors: Wen-Wann Sheen, Taipei County (TW); Ming-Hsin Chan, Xizhi City (TW)

Correspondence Address: BIRCH STEWART KOLASCH & BIRCH, PO BOX 747, FALLS CHURCH, VA, 22040-0747, US

(73) Assignee: Princeton Technology Corporation

(21) Appl. No.: 11/700,774

(22) Filed: Feb. 1, 2007

(30) Foreign Application Priority Data
Jul. 26, 2006 (TW) 095127272

(51) Int. Cl. H03K 3/36

(52) U.S. Cl. 331/111

(57) ABSTRACT

An oscillator comprising a compensation circuit, an oscillating module and a controller are disclosed. The compensation circuit comprises a charging circuit and a discharging circuit. The charging circuit comprises a first current source coupled between a voltage source and a second transistor, and the second transistor having a second first terminal coupled to a first current source, a second second terminal coupled to a first node, and a second gate for receiving a first switching signal. The discharging circuit comprises a third transistor having a third first terminal coupled to the first node and a third gate for receiving a second switching signal, and a second current source coupled between the third transistor and ground. The oscillating module couples between the compensation circuit and the controller and generates an output signal. The controller generates the first switching signal and the second switching signal according to the output signal.

### BACKGROUND OF THE INVENTION

1. Field of the Invention

The invention relates to an oscillator, and more particularly relates to an oscillator with low voltage, process variation and temperature sensitivity.

2. Description of the Related Art

FIG. 1 is a schematic view of a conventional RC oscillator 100. RC oscillator 100 comprises three inverters 102, 104 and 108, capacitor C1, resistor R1 and inverting unit 106.

Inverter 102 has an input terminal coupled to node N11 and an output terminal. Inverter 104 has an input terminal coupled to the output terminal of inverter 102 and an output terminal coupled to node N12. Capacitor C1 is coupled between node N11 and node N12. Resistor R1 is coupled between node N11 and node N13. Inverting unit 106 is coupled between node N12 and node N13. Inverter 108 has an input terminal coupled to node N13 and an output terminal for generating an output signal 110.

Inverting unit 106 can be an NAND gate or an inverter. In this example inverting unit 106 is a NAND gate. To reduce power consumption, RC oscillator 100 can be enabled or disabled according to an enable signal EN.

An oscillation frequency of RC oscillator 100 is determined by time constants of resistor R1 and capacitor C1.

In wafer fabrication, capacitor C1 can be one of a metal-insulator-metal (MIM) capacitor, a poly-insulator-poly (PIP) capacitor and a metal-oxide-semiconductor (MOS) capacitor. In addition, resistor R1 in RC oscillator 100 can be high-R poly or long-channel MOS transistor.

MIM capacitor errors caused by process variation may be 10˜20%, and the error of the MOS capacitor caused by process variation and voltage may be 10%. Further, the error of the high-R poly caused by process variation may be 20%, and that of the long channel MOS transistor caused by process variation may be 10%. In addition, the error of the long channel MOS transistor is inversely proportional to the voltage square.

The oscillation frequency of RC oscillator 100 is determined by time constants of resistor R1 and capacitor C1, and the resistance of resistor R1 and the capacitance of capacitor C1 may have error caused by process variation and voltage. Thus, the oscillation frequency of RC oscillator 100 is significantly influenced by process variation and voltage (e.g. different generated RC values).

Thus, resolving the oscillation frequency of RC oscillator 100 influenced by process variation and voltage is desirable.

### BRIEF SUMMARY OF INVENTION

A detailed description is given in the following embodiments with reference to the accompanying drawings.

The invention provides an oscillator comprising a compensating circuit, an oscillating module and a controller. The compensating circuit comprises a charging circuit and a discharging circuit. The charging circuit comprises a first current source and a second transistor, the first current source is coupled between a voltage source and the second transistor, the second transistor has a second first terminal coupled to the first current source, a second second terminal coupled to a first node, and a second gate for receiving a first switching signal. The discharging circuit comprises a third transistor and a second current source, the third transistor has a third first terminal coupled to the first node, a third second terminal, and a third gate for receiving a second switching signal, and the second current source is coupled between the third transistor and ground. The oscillating module comprises a first inverter, a second inverter, a capacitor, a resistor, a third inverter and a fourth inverter. The first inverter has a first input terminal coupled to the first node and a first output terminal. The second inverter has a second input terminal coupled to the first output terminal and a second output terminal coupled to a second node. The capacitor is coupled between the first node and the second node. The resistor is coupled between the first node and a third node. The third inverter is coupled between the second node and the third node. The fourth inverter has a fourth input terminal coupled to the third node, and a fourth output terminal for generating an output signal. Controller is coupled to the charging circuit, discharging circuit and the fourth inverter for generating the first switching signal and the second switching signal according to the output signal.

### BRIEF DESCRIPTION OF DRAWINGS

The invention can be more fully understood by reading the subsequent detailed description and examples with references made to the accompanying drawings, wherein:

FIG. 1 is a schematic view of a conventional RC oscillator.

FIG. 2A is a schematic view of an RC oscillator according to an embodiment of the invention.

FIG. 2B is a schematic view of an RC oscillator according to another embodiment of the invention.

FIG. 3 is a schematic view of a compensating circuit according to an embodiment of the invention.

FIG. 4A shows the relationship between operating voltages versus output signal OSCO.

FIG. 4B shows the relationship between operating voltages versus first switching signal SW1.

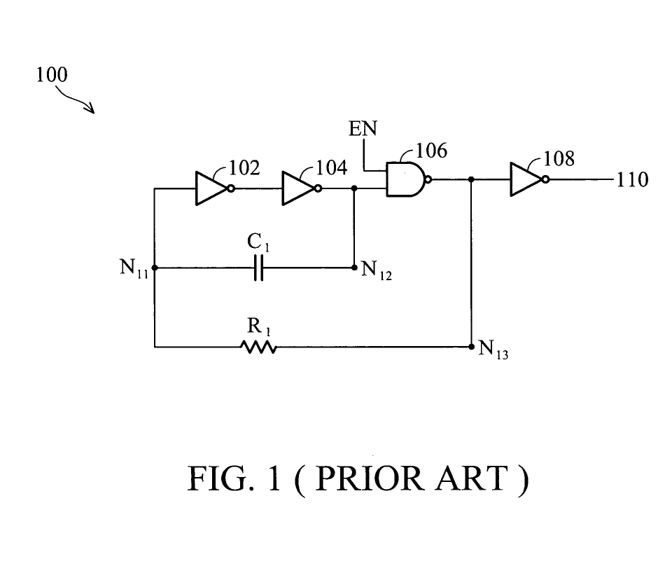

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

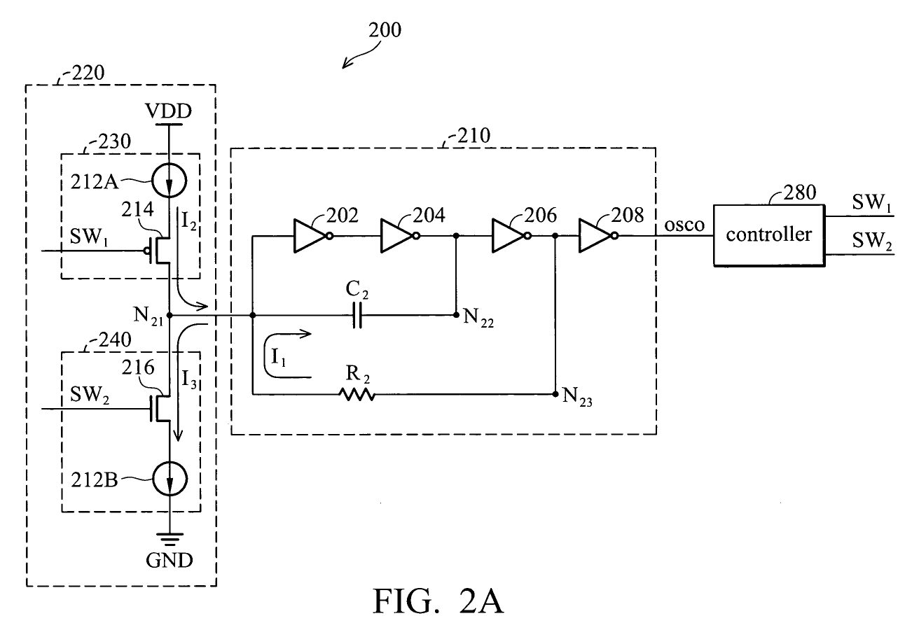

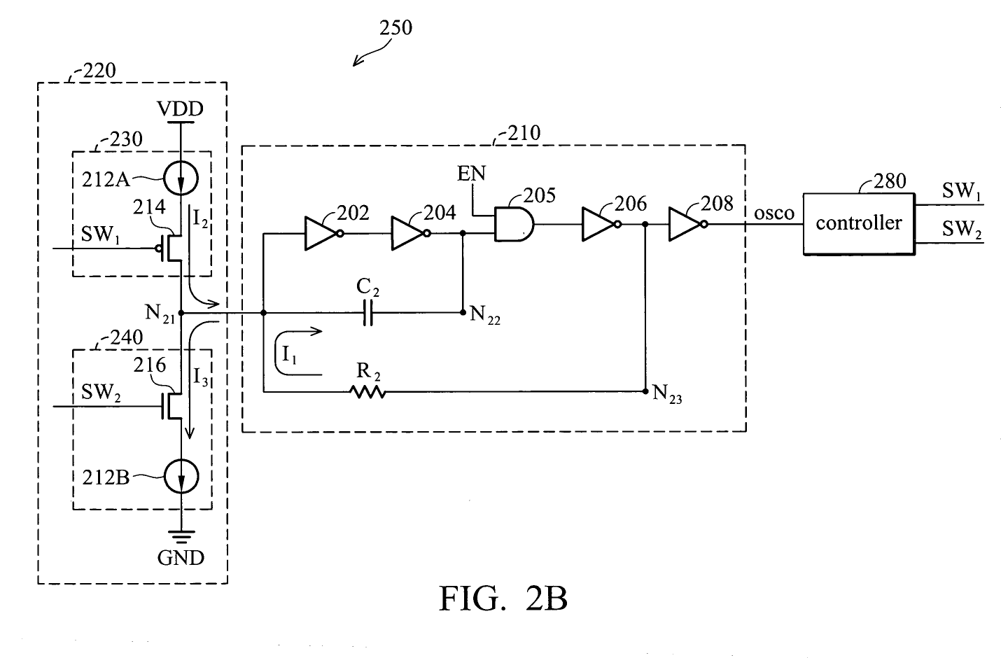

FIG. 2A is a schematic view of an RC oscillator 200 according to an embodiment of the invention. RC oscillator 200 comprises compensating circuit 220, oscillating module 210 and controller 280. Compensating circuit 220 comprises charging circuit 230 and discharging circuit 240.

Charging circuit 230 comprises first current source 212A and second transistor 214. First current source 212A is coupled between voltage source VDD and second transistor 214. Second transistor 214 has a second first terminal coupled to first current source 212A, a second second terminal coupled to first node N21, and a second gate for receiving first switching signal SW1.

Discharging circuit 240 comprises third transistor 216 and second current source 212B. Third transistor 216 has a third first terminal coupled to first node N21, third second terminal coupled to second current source 212B, and a third gate for receiving second switching signal SW2. Second current source 212B is coupled between third transistor 216 and ground GND.

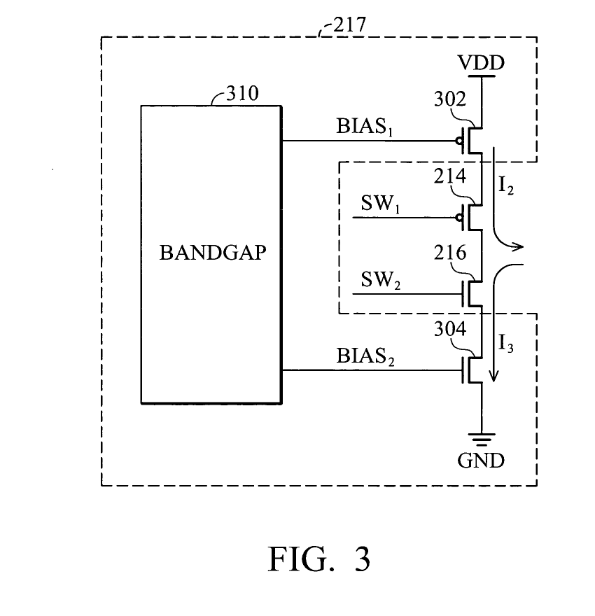

FIG. 3 is a schematic view of a compensating circuit according to an embodiment of the invention. Referring to FIG. 2A and FIG. 3, compensating circuit 220 comprises current supply circuit 217, second transistor 214 and third transistor 216.

Current supply circuit 217 comprises first current source 212A and second current source 212B. Note that first current source 212A and second current source 212B in accordance with an embodiment may comprises bandgap circuit BANDGAP 310, first transistor 302 and fourth transistor 304. First transistor 302 has a first first terminal coupled to voltage source VDD, a first second terminal coupled to the second first terminal, and a first gate for receiving first bias signal Bias1. Fourth transistor 304 has a fourth first terminal coupled to the third second terminal, a fourth second terminal coupled to ground GND, and a fourth gate for receiving second bias signal Bias2.

Bandgap circuit 310 provides first bias signal Bias1 and second bias signal Bias2 respectively for selectively turning on first transistor 302 and fourth transistor 304 to form the required current path (i.e. charging current path I2 or discharging current path I3) respectively.

In addition, first current source 212A and second current source 212B can be composed of a current mirror according to another embodiment of the invention.

Note that first transistor 302 and second transistor 214 are preferably PMOS transistors, and third transistor 216 and fourth transistor 304 are preferably NMOS transistors.

Referring to FIG. 2A, oscillation module 210 according to an embodiment of the invention, comprises inverter 202, 204, 206 and 208, capacitor C2 and resistor R2.

First inverter 202 has a first input terminal coupled to first node N21, and a first output terminal. Second inverter 204 has a second input terminal coupled to the first output terminal of first inverter 202, and a second output terminal coupled to second node N22. Resistor R2 is coupled between first node N21 and third node N23. Third inverter 206 is coupled between second node N22 and third node N23. Fourth inverter 208 has a fourth input terminal coupled to node N23, and a fourth output terminal for generating output signal OSCO.

Controller 280 in accordance with an embodiment of the invention generates first switching signal SW1 and second switching signal SW2 according to the output signal OSCO. Note that controller 280 can be a delay unit.

Referring to FIG. 2B, RC oscillator 250 in accordance with another embodiment of the invention is substantially similar to RC oscillator 200 shown in FIG. 2A, except that oscillation module 210 further comprises AND gate 205 for enabling or disabling oscillation module 210 according to enabling signal EN to reduce power consumption of RC oscillator 250.

In this embodiment, capacitor C2 is the MOS capacitor and resistor R2 is the MOS long channel MOS transistor. The characteristic of the MOS capacitor is that the capacitance of the MOS capacitor may not influenced by voltage when the operating voltage exceeds a predetermined value. However, the resistance of resistor R2 (i.e. long channel MOS transistor is in inverse proportion to square of the operating voltage square. Thus, the time constant RC of capacitor C2 and resistor R2 may be different under different operating voltage and different process variation.

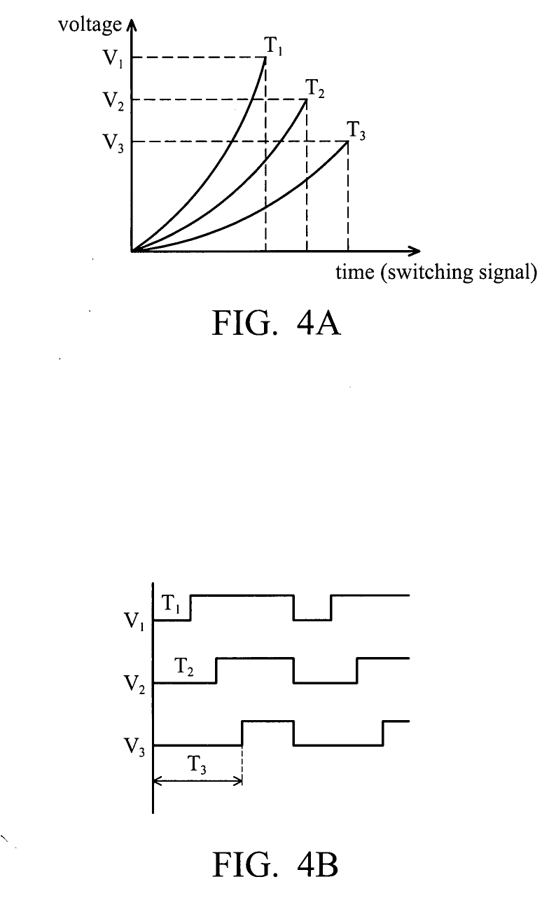

FIG. 4A shows the relationship between operating voltages versus output signal OSCO. FIG. 4B shows the relationship between operating voltages versus first switching signal SW1. Obviously, the greater the operating voltage (V1>V2>V3) the smaller the period of output signal OSCO (T1<T2<T3). Thus, the turn on time of second transistor 214 is longer when the voltage is smaller, while the turn on time of second transistor 214 is shorter when the voltage is greater.

For example, the resistance of resistor R2 may be reduced when the voltage is increased, such that the current in current path I2 through resistor R2 and capacitor C2 may be increased. Referring to FIG. 4A and FIG. 4B, the turn on time of second transistor 214 is shortened when the voltage is increased, such that the compensating current generated from charging current path I2 is smaller.

In addition, the resistance of resistor R2 may be increased when the voltage is reduced, such that the current in current path I1 through resistor R2 and capacitor C2 may be reduced. Referring to FIG. 4A and FIG. 4B, the turn on time of second transistor 214 is increased when the voltage is reduced, such that the compensating current generated from charging current path I2 is larger.

Note that current supply path 217 is a current source not sensitive to voltage, process variation and temperature, thus, charging current path I2 and discharging current path I3 may not be influenced by voltage, process variation and temperature.

Thus, controller 280 generates first switching signal SW1 and second switching signal SW2 according to output signal OSCO for controlling the turn on time of second transistor 214 and third transistor 216 respectively, such that charging current path I2 and discharging current path I3 provided by compensating circuit 220 may be used to compensate current in current path I1.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An oscillator, comprising:
a compensating circuit, comprising:
a charging circuit comprising a first current source and a second transistor, the first current source is coupled between a voltage source and the second transistor, the second transistor has a second first terminal coupled to the first current source, a second second terminal coupled to a first node, and a second gate for receiving a first switching signal; and
a discharging circuit comprising a third transistor and a second current source, the third transistor has a third first terminal coupled to the first node, a third second terminal, and a third gate for receiving a second switching signal, the second current source is coupled between the third transistor and a ground;
an oscillating module, comprising:
a first inverter having a first input terminal coupled to the first node, and a first output terminal;
a second inverter having a second input terminal coupled to the first output terminal, and a second output terminal coupled to a second node;
a capacitor coupled between the first node and the second node;
a resistor coupled between the first node and a third node;
a third inverter coupled between the second node and the third node; and
a fourth inverter having a fourth input terminal coupled to the third node, and a fourth output terminal for generating an output signal; and
a controller coupled to the charging circuit, discharging circuit and the fourth inverter for generating the first switching signal and the second switching signal according to the output signal.

2. The oscillator as claimed in claim 1, wherein the first current source and the second current source comprises a bandgap circuit, a first transistor and a fourth transistor.

3. The oscillator as claimed in claim 2, wherein the first transistor has a first first terminal coupled to the voltage source, a first second terminal coupled to the second first terminal, and a first gate for receiving a first bias signal.

4. The oscillator as claimed in claim 3, wherein the fourth transistor has a fourth first terminal coupled to the third second terminal, a fourth second terminal coupled to the ground, and a fourth gate for receiving a second bias signal.

5. The oscillator as claimed in claim 4, wherein the bandgap circuit provides the first bias signal and the second bias signal respectively to selectively turn on the first transistor and the fourth transistor.

6. The oscillator as claimed in claim 2, wherein the first transistor and the second transistor are PMOS transistor, and the third transistor and the fourth transistor are NMOS transistor.

7. The oscillator as claimed in claim 1, wherein the first current source and the second current source respectively comprise a current mirror.

8. The oscillator as claimed in claim 1, wherein the controller is a delay unit.

9. The oscillator as claimed in claim 1, further comprising an AND gate coupled between the second inverter and the third inverter for enabling or disabling the oscillating module according to an enable signal.

10. An oscillator, comprising:
an oscillating module, comprising:
a first inverter having a first input terminal coupled to a first node, and a first output terminal;
a second inverter having a second input terminal coupled to the first output terminal, and a second output terminal coupled to a second node;
a capacitor coupled between the first node and the second node;
a resistor coupled between the first node and a third node;
a third inverter coupled between the second node and the third node; and
a fourth inverter having a fourth input terminal coupled to the third node, and a fourth output terminal for generating an output signal;
a charging circuit coupled between a voltage source and the first node for providing a charging path to the oscillating module according to a first bias signal and a second switching signal; and
a discharging circuit coupled between the first node and a ground for providing a discharging path to the oscillating module according to a second bias signal and a second switching signal; and
a controller coupled to the charging circuit, discharging circuit and the fourth inverter for generating the first switching signal and the second switching signal according to the output signal.

11. The oscillator as claimed in claim 10, further comprising a AND gate coupled between the second inverter and the third inverter for enabling or disabling the oscillating module according to an enable signal.

12. The oscillator as claimed in claim 10, wherein the charging circuit comprises a first current source and a second transistor, the first current source is coupled between the voltage source and the second transistor, the second transistor has a second first terminal coupled to the first-current source, a second second terminal coupled to the first node, and a second gate for receiving the first switching signal.

13. The oscillator as claimed in claim 12, wherein the discharging circuit comprising a third transistor and a second current source, the third transistor has a third first terminal coupled to the first node, a third second terminal, and a third gate for receiving the second switching signal, the second current source is coupled between the third transistor and the ground.

14. The oscillator as claimed in claim 13, wherein the first current source and the second current source comprises a bandgap circuit, a first transistor and a fourth transistor.

15. The oscillator as claimed in claim 14, wherein the first transistor has a first first terminal coupled to the voltage source, a first second terminal coupled to the second first terminal, and a first gate for receiving the first bias signal.

16. The oscillator as claimed in claim 15, wherein the fourth transistor has a fourth first terminal coupled to the third second terminal, a fourth second terminal coupled to the ground, and a fourth gate for receiving the second bias signal.

17. The oscillator as claimed in claim 15, wherein the bandgap circuit provides the first bias signal and the second bias signal respectively to selectively turn on the first transistor and the fourth transistor.

18. The oscillator as claimed in claim 14, wherein the first transistor and the second transistor are PMOS transistors, and the third transistor and the fourth transistor are NMOS transistors.

19. The oscillator as claimed in claim 13, wherein the first current source and the second current source respectively comprise a current mirror.

20. The oscillator as claimed in claim 10, wherein the controller is a delay component.
